(19) United States
(12) Patent Application Publication
(10) Pub. No.: US 2022/0270958 A1
(43) Pub. Date: Aug. 25, 2022

(54) ELECTRONIC ELEMENT MOUNTING SUBSTRATE, ELECTRONIC DEVICE, ELECTRONIC MODULE, AND METHOD FOR MANUFACTURING ELECTRONIC ELEMENT MOUNTING SUBSTRATE

(71) Applicant: KYOCERA Corporation, Kyoto-shi, Kyoto (JP)

(72) Inventor: Akihiko FUNAHASHI, Kyoto-shi (JP)

(73) Assignee: KYOCERA Corporation, Kyoto-shi, Kyoto (JP)

(21) Appl. No.: 17/630,194

(22) PCT Filed: Jul. 29, 2020
(86) PCT No.: PCT/JP2020/029070

§ 371 Date: Jan. 26, 2022

(30) Foreign Application Priority Data
Jul. 30, 2019 (JP) 2019-139890

(51) Int. Cl. H01L 23/498; H01L 21/48

(52) U.S. Cl. CPC H01L 23/49822; H01L 21/4857; H01L 21/486; H01L 23/49838; H01L 2224/73265; H01L 27/14618

(57) ABSTRACT

An electronic element mounting substrate includes a first insulating layer, a second insulating layer, a first metal layer, and a through-hole conductor. The first insulating layer and the second insulating layer are aligned in a first direction. The first metal layer is positioned between the first insulating layer and the second insulating layer. The through-hole conductor extends in the first direction from the first insulating layer through the second insulating layer. The first metal layer includes a first portion positioned away from the through-hole conductor and a second portion in contact with the through-hole conductor. The second portion has a larger thickness than the first portion.

### TECHNICAL FIELD

The present disclosure relates to an electronic element mounting substrate on which an electronic element or other components are mounted, an electronic device, an electronic module, and a method for manufacturing an electronic element mounting substrate.

### BACKGROUND ART

A known electronic element mounting substrate includes an insulating layer and a wiring layer and is provided with a through-hole conductor.

In recent years, electronic elements have been required to have higher functionality, thus requiring a larger number of terminals. For this reason, electronic element mounting substrates on which an electronic element is mounted are being provided with an increasing number of portions for connection to wiring layers above, below, or within the same layer, and thus high connection reliability is required. A method is available for layering insulating layers each including a conductor that extends through the layer, that is, a through-hole conductor, to achieve vertical connection. However, there are concerns about misalignment of the conductors in the insulating layers between the upper and lower layers due to process errors or the like, leading to electrical disconnection and/or unintended electrical connection. Furthermore, the size of the conductor in each insulating layer cannot be reduced and/or the distance between the through-hole conductors cannot be reduced, which hinders higher density wiring in the electronic element mounting substrate.

Patent Document 1 describes, as a method for manufacturing an electronic element mounting substrate, a method of forming a laminate including an insulating layer and a wiring layer, forming through holes using a laser, and thereafter producing through-hole conductors in the through holes in order to improve electrical connection between through-hole conductors in upper and lower layers (see Japanese Unexamined Patent Application Publication No. 2017-183337).

As a method for forming a through hole in a laminate formed by layering insulating layers, there is a method including forming the through hole by punching with a pin using a mold and producing a through-hole conductor in the through hole. A wiring layer (internal wiring) that assists electrical connection with the through-hole conductor may become deformed when pressed by the pin during punching. This deformation may cause the contact area between the through-hole conductor and the internal wiring to decrease and electrical resistance to increase, which hinders higher functionality of electronic devices. To address this, there is a demand for current electronic element mounting substrates to have high connection reliability between the through-hole conductor and the internal wiring.

### SUMMARY OF INVENTION

An electronic element mounting substrate according to one aspect of the present disclosure includes a first insulating layer, a second insulating layer, a first metal layer, and a through-hole conductor. The first insulating layer and the second insulating layer are aligned in a first direction. The first metal layer is positioned between the first insulating layer and the second insulating layer. The through-hole conductor extends in the first direction from the first insulating layer through the second insulating layer. The first metal layer includes a first portion positioned away from the through-hole conductor and a second portion in contact with the through-hole conductor. The second portion has a larger thickness than the first portion.

An electronic device according to one aspect of the present disclosure includes the above-described electronic element mounting substrate, and an electronic element mounted on the electronic element mounting substrate.

An electronic module according to one aspect of the present disclosure includes the above-described electronic device, and a casing that covers the electronic device and is included in the electronic device.

A method for manufacturing an electronic element mounting substrate according to one aspect of the present disclosure includes a first step to a fifth step. In the first step, a first insulating layer and a second insulating layer are prepared. In the second step, a first metal layer having different thicknesses is disposed on the second insulating layer. In the third step, a first insulating layer is layered on the second insulating layer with the first metal layer interposed therebetween to obtain a first laminate. In the fourth step, a through hole that extends through the first laminate is formed, the through hole extending through a thick portion of the first metal layer in a layering direction. In the fifth step, a through-hole conductor is formed in the through hole.

A method for manufacturing an electronic element mounting substrate according to one aspect of the present disclosure includes step A to step E. In step A, a metal layer A, a metal layer B, a first insulating layer, and a second insulating layer are prepared. In step B, the metal layer A and the metal layer B are disposed at least partially overlapping between the first insulating layer and the second insulating layer. In step C, the first insulating layer, the metal layer A, the metal layer B, and the second insulating layer are sequentially layered to obtain a second laminate. In step D, a through hole that extends through the second laminate is formed, the through hole extending through a portion in which the metal layer A and the metal layer B overlap each other in a layering direction. Then, in step E, a through-hole conductor is formed in the through hole.

### BRIEF DESCRIPTION OF DRAWINGS

FIG. 1A is a top view of an electronic element mounting substrate and an electronic device according to a first embodiment of the present disclosure, and FIG. 1B is a cross-sectional view taken along line X1-X1 in FIG. 1A.

FIG. 2A is a top view of an electronic module according to another aspect of the first embodiment of the present disclosure, and FIG. 2B is a cross-sectional view taken along line X2-X2 in FIG. 2A.

FIG. 3 is an enlarged view of a main part A in FIG. 1B.

FIG. 4 is an enlarged view of the configuration illustrated in FIG. 2 at a position corresponding to the main part A in FIG. 1.

FIG. 5 is an enlarged view according to another aspect at the position corresponding to the main part A in FIG. 1.

FIGS. 6A and 6B are schematic views illustrating a method for manufacturing the electronic element mounting substrate according to the first embodiment of the present disclosure.

FIGS. 7A and 7B are schematic views illustrating the method for manufacturing the electronic element mounting substrate according to the first embodiment of the present disclosure.

FIG. 8 is a schematic view illustrating another aspect of the method for manufacturing the electronic element mounting substrate according to the first embodiment of the present disclosure.

FIG. 9 is a schematic view illustrating another aspect of the method for manufacturing the electronic element mounting substrate according to the first embodiment of the present disclosure.

FIG. 10A is a schematic view of the periphery of a through-hole conductor in an electronic element mounting substrate according to a second embodiment of the present disclosure, as viewed in a first direction, and FIG. 10B is a cross-sectional view taken along line X10-X10 in FIG. 10A.

FIG. 11A is a schematic view of the periphery of a through-hole conductor in an electronic element mounting substrate according to a third embodiment of the present disclosure, as viewed in the first direction, and FIG. 11B is a cross-sectional view taken along line X11-X11 in FIG. 11A.

FIG. 12 is a cross-sectional view of an electronic element mounting substrate according to an aspect of a fourth embodiment of the present disclosure at the position corresponding to the main part A in FIG. 1.

FIG. 13 is a cross-sectional view of an electronic element mounting substrate according to an aspect of a fifth embodiment of the present disclosure at the position corresponding to the main part A in FIG. 1.

FIG. 14 is a cross-sectional view of an electronic element mounting substrate according to an aspect of a sixth embodiment of the present disclosure at the position corresponding to the main part A in FIG. 1.

FIG. 15A is a schematic view of the periphery of a through-hole conductor in the electronic element mounting substrate according to the first embodiment of the present disclosure, as viewed in the first direction, and FIG. 15B is a cross-sectional view taken along line X15-X15 in FIG. 15A.

### DESCRIPTION OF EMBODIMENTS

### Configuration of Electronic Element Mounting Substrate and Electronic Device

Several exemplary embodiments of the present disclosure will be described hereinafter with reference to the drawings. In the following description, a configuration in which an electronic element is mounted on an electronic element mounting substrate is defined as an electronic device. A configuration including a casing that covers the electronic device provided on the electronic element mounting substrate is defined as an electronic module. With respect to the electronic element mounting substrate, the electronic device, and the electronic module, any direction may be defined as upward or downward, but for the sake of simplicity, the Cartesian coordinate system XYZ will be used herein, with a positive side in the Z direction defined as upward. The direction from the upper side to the lower side is defined as a first direction.

### First Embodiment

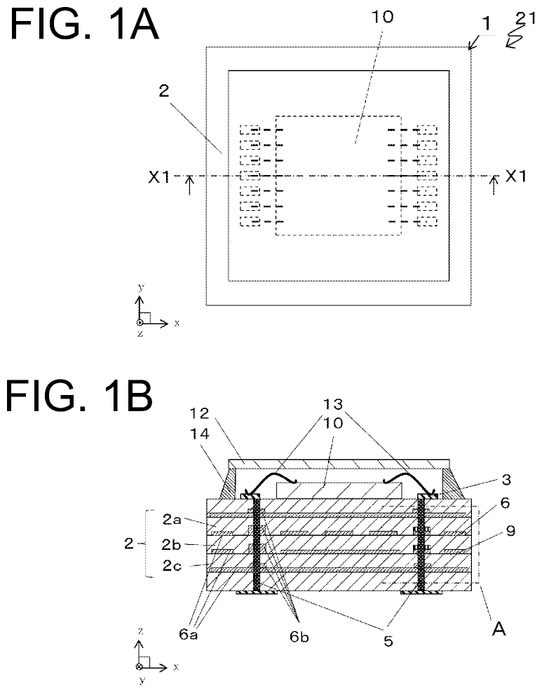

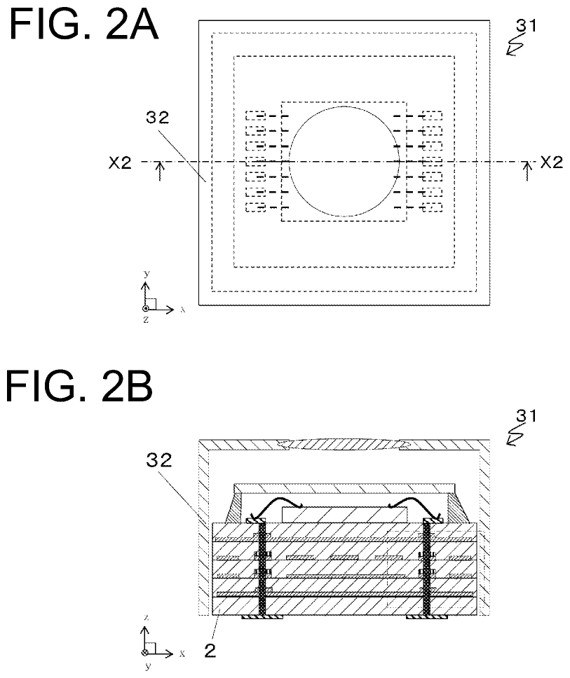

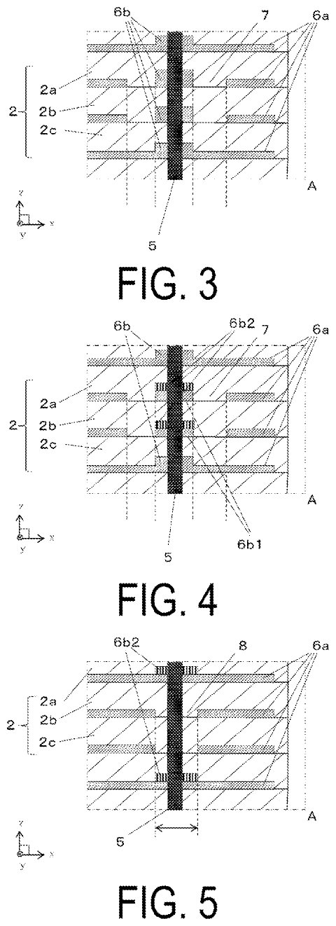

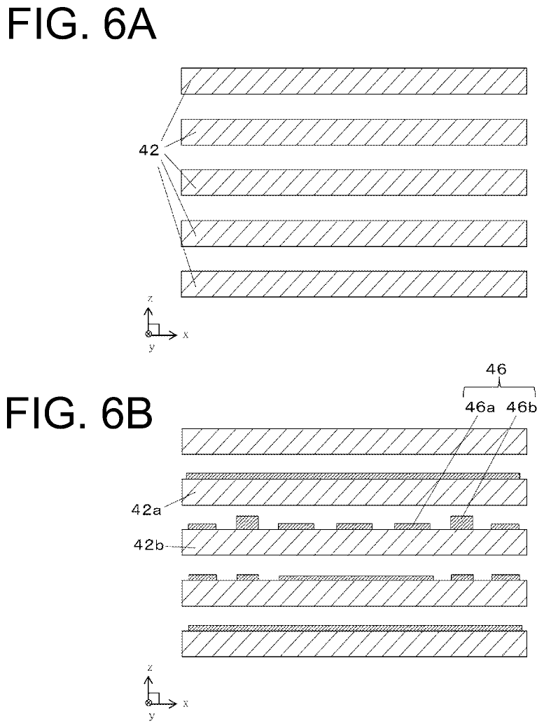

An electronic element mounting substrate and an electronic device including the electronic element mounting substrate according to a first embodiment of the present disclosure will be described with reference to FIGS. 1 to 9. Note that FIG. 1 illustrates a top view and a cross-sectional view of the electronic device 21, and FIG. 2 illustrates a top view and a cross-sectional view of an electronic module 31. FIGS. 3 to 5 are examples of enlarged views of a main part A in FIG. 1 and positions corresponding to the main part A in FIG. 1. Further, FIGS. 6 to 9 are schematic views of a method for manufacturing an electronic element mounting substrate 1.

The electronic element mounting substrate 1 includes a mounting region 4 in which an electronic element 10 is to be mounted. The electronic element mounting substrate 1 includes at least a first insulating layer 2a and a second insulating layer 2b aligned in the first direction. The electronic element mounting substrate 1 also includes a first metal layer 6 that is internal wiring between the first insulating layer 2a and the second insulating layer 2b. The electronic element mounting substrate 1 further includes through-hole conductors 5 extending in the first direction from the first insulating layer 2a through the second insulating layer 2b. Note that in FIG. 1, the through-hole conductor 5 extends through five insulating layers.

The first metal layer 6 includes a first portion 6a and a second portion 6b in contact with the through-hole conductor 5. The second portion 6b has a larger thickness than the first portion 6a.

Here, the term “thickness” refers to a dimension in the first direction. In other words, the term “thickness” refers to a dimension in the layering direction. The mounting region 4 is a region on which at least one electronic element 10 is mounted, and can be appropriately defined as, for example, inside or outside the outermost periphery of electrode pads 3, which will be described later. Further, the electronic element 10 mounted on the mounting region 4 is not limited to an electronic element, and may be, for example, an electronic component. Furthermore, the number of the mounted electronic elements 10 is not particularly limited.

The electronic element mounting substrate 1 includes a plurality of insulating layers, including the first insulating layer 2a and the second insulating layer 2b. In the following, the plurality of insulating layers are collectively referred to as the insulating layers 2.

Examples of the electrically insulating ceramic used as the material for the insulating layers 2 include an aluminum oxide-based sintered compact, a mullite-based sintered compact, a silicon carbide sintered compact, an aluminum nitride-based sintered compact, a silicon nitride-based sintered compact, and a glass ceramic sintered compact. Examples of the material for the insulating layers 2 also include a resin, examples of which include a thermoplastic resin, an epoxy resin, a polyimide resin, an acrylic resin, a phenol resin, and a fluorine-based resin.

The plurality of insulating layers 2 are at least two or more layers, and may be five layers as illustrated in FIG. 1, or may be four or less layers or six or more layers. When the plurality of insulating layers 2 all have the same thickness, the electronic element mounting substrate 1 can be made thinner because a smaller number of insulating layers 2 are layered. Further, when the plurality of insulating layers 2 all have the same thickness, when a larger number of insulating layers 2 are layered, the rigidity of the electronic element mounting substrate 1 can be increased.

The size of one side of the outermost periphery of the electronic element mounting substrate 1 may be, for example, 0.3 mm to 10 cm. When the electronic element mounting substrate 1 has a quadrilateral shape in a top view, the electronic element mounting substrate 1 may be square or rectangular. For example, the thickness of the electronic element mounting substrate 1 may be 0.2 mm or more.

External circuit connection electrodes may be provided on the top surface, the side surfaces, or the bottom surface of the electronic element mounting substrate 1. The external circuit connection electrodes electrically connect the electronic element mounting 1 and an external circuit board.

In addition to the first metal layer 6 formed between the insulating layers 2, the through-hole conductors 5, the electrode pads 3, and the external circuit connection electrodes, the electronic element mounting substrate 1 may be provided with electrodes and wiring conductors that are other metal layers, and through-hole conductors, other than the through-hole conductor 5, that vertically connect the wiring conductors to each other. Wiring other than these electrodes, the wiring conductors, and the through-hole conductors 5 may be positioned only on the surface of the electronic element mounting substrate 1, only inside the electronic element mounting substrate 1, or both on the surface and inside the electronic element mounting substrate 1.

When the insulating layer 2 is made of an electrically insulating ceramic, the material of the first metal layer 6, the through-hole conductor 5, the electrode pad 3, the external circuit connection electrode, and the other metal layers may be tungsten (W), molybdenum (Mo), manganese (Mn), palladium (Pd), silver (Ag), or copper (Cu), or an alloy containing at least one metal material selected from these metals. When the insulating layer 2 is made of a resin, the material of the first metal layer 6, the through-hole conductor 5, the electrode pad 3, the external circuit connection electrode, and the other metal layers may be copper (Cu), gold (Au), aluminum (Al), nickel (Ni), molybdenum (Mo), palladium (Pd), or titanium (Ti), or an alloy containing at least one metal material selected from these metals.

The first metal layer 6, the through-hole conductor 5, the electrode pads 3, the external circuit connection electrodes, and the other metal layers may further include a plating layer on their top surfaces or portions exposed from the insulating layer 2. With this configuration, the top surfaces or portions exposed from the insulating layer 2 are protected, and thus oxidation can be reduced. In addition, according to this configuration, the electrode pads 3 and the electronic element 10 can be favorably electrically connected via electronic element bonding members 13 such as wire bonding. The plating layer may be, for example, formed by depositing a nickel (Ni) plating layer having a thickness of from 0.5 μm to 10 μm, or by sequentially depositing the Ni plating layer and a gold (Au) plating layer having a thickness of from 0.5 μm to 3 μm.

As illustrated in FIG. 3, the first metal layer 6 includes a first portion 6a and a second portion 6b in contact with the through-hole conductor 5. The second portion 6b has a larger thickness than the first portion 6a. The first portion 6a is positioned away from the through-hole conductor 5. Here, the first portion 6a and the second portion 6b are distinguished from each other by their thicknesses, and may be made of the same or different materials. Note that the thickness is a length in the vertical direction, based on a cross section taken along the first direction such as that illustrated in FIG. 3. The second portion 6b of the first metal layer 6 is positioned such to increase the connection reliability between the through-hole conductor 5 that extends through the plurality of insulating layers 2 and the metal layers located between the plurality of insulating layers 2.

Because the second portion 6b, which is in contact with the through-hole conductor 5, has a larger thickness than the first portion 6a, the contact area between the second portion 6b and the through-hole conductor 5 is large, which is less likely to prevent higher functionality of the electronic device due to increased electrical resistance.

Furthermore, when the second portion 6b has a larger thickness than the first portion 6a, in the process of forming a through hole to form the through-hole conductor 5, the through hole is formed so as to include the second portion 6b, and thereafter the through-hole conductor 5 is formed. With this configuration, even when deformation occurs when pressing with a pin, the contact area between the second portion 6b and the through-hole conductor 5 is large, which is less likely to prevent higher functionality of the electronic device due to increased electrical resistance.

Here, the first metal layer 6 including the first portion 6a and the second portion 6b may be positioned between a plurality of the insulating layers 2, or only one first metal layer 6 may be provided between the first insulating layer 2a and the second insulating layer 2b. The first metal layer 6 positioned at a location other than between the first insulating layer 2a and the second insulating layer 2b may be referred to as another metal layer 6c. Furthermore, the second portion 6b may be positioned at a plurality of locations or at only one location between the insulating layers 2. Furthermore, when the second portions 6b are positioned at a plurality of locations, the second portions 6b may have different thicknesses in a cross-sectional view.

FIGS. 3 to 6 illustrate examples of enlarged views of the main part A (or a part corresponding to the main part A) of the present embodiment.

In the example illustrated in FIG. 3, the thickness of one layer of the second portion 6b is larger than that of the first portion 6a. In other words, the second portion 6b is made thicker than the first portion 6a by a single application or printing. In the example illustrated in FIG. 4, the thickness of a total of at least two layers of the second portion 6b is larger than that of the first portion 6a. In either case, the advantageous effects of the present embodiment can be obtained.

As in the example illustrated in FIG. 3, the second portion 6b is made thicker than the first portion 6a by a single application or printing, and thus process errors are less likely to occur in a step of applying or printing a paste to be the first metal layer 6. Thus, the clearance between the second portion 6b and the first portion 6a can be ensured with high accuracy and, even if the electronic element mounting substrate 1 is densely wired, less unwanted short-circuiting occurs between wiring lines for different signals.

As in the example illustrated in FIG. 4, the thickness of a total of two layers of the second portion 6b is larger than that of the first portion 6a. In other words, the paste to be the first metal layer 6 is applied or printed twice. As a result, when a portion having the same thickness as the first portion 6a is referred to as a first layer 6b1 and a portion positioned on the first layer is referred to as a second layer 6b2, for example, a metal component or the like can be added as appropriate to a paste to be the second layer 6b2 to improve characteristics or change the viscosity. As an example of improving characteristics, electrical characteristics can be improved by adding a low resistance material such as copper, for example. Furthermore, using a material having a low viscosity can suppress deformation of the second portion 6b when a pin is pressed.

The first metal layer 6 may include a first clearance portion 7 between the second portion 6b and the first portion 6a. In other words, the second portion 6b may be positioned away from the first portion 6a by the first clearance portion 7. When such a configuration is satisfied, for example, the first portion 6a can be used as a wiring layer that passes a signal different from a signal passing through the through-hole conductor 5, and this contributes to high density wiring.

As illustrated in FIG. 1, when a third insulating layer 2c aligned with the second insulating layer 2b in the first direction and a second metal layer 9 positioned between the second insulating layer 2b and the third insulating layer 2c are provided, a second clearance portion 8 may be provided between the through-hole conductor 5 and the second metal layer 9. In other words, the through-hole conductor 5 may be positioned away from the second metal layer 9 by the second clearance portion 8. When such a configuration is satisfied, the second metal layer 9 can be used as a wiring layer that passes a signal different from a signal passing through the through-hole conductor 5 and the first portion 6a, and this contributes to high density wiring. When higher density wiring for the electronic element mounting substrate 1 is achieved, the electronic device 21 can be given higher functionality and be downsized. Note that the second metal layer 9 need not necessarily be wiring that passes a signal different from a signal passing through the first portion 6a, and may be used as wiring that connects with another through-hole conductor to pass the same signal.

As illustrated in the example illustrated in FIG. 5, the second portion 6b may be positioned in the second clearance portion 8 when viewed in a plane perspective in the first direction. In the example illustrated in FIG. 5, an example is illustrated in which the outer edges of the second portion 6b overlap the inner edges of the second clearance portion 8. Thus, being positioned in the second clearance portion 8 includes overlapping the second clearance portion 8. When such a configuration is satisfied, the second portion 6b becoming thicker than the first portion 6a after layering the layers of the second portion 6b is alleviated, and thus bulging at the surface around the through-hole conductor 5 in the electronic element mounting substrate 1 can be reduced.

In other words, because the second clearance portion 8 is provided, depression at the surface around the through-hole conductor 5 in the electronic element mounting substrate 1 can be reduced.

The second clearance portion 8 may be positioned in the second portion 6b when viewed in a plane perspective in the first direction. When such a configuration is satisfied, bulging and depression of the surface at a portion proximate to the through-hole conductor 5 can be reduced, and high density wiring can be achieved.

### Configuration of Electronic Device

An example of the electronic device 21 is illustrated in FIG. 1. The electronic device 21 includes the electronic element mounting substrate 1 and the electronic element 10 mounted on the upper surface of the electronic element mounting substrate 1.

Examples of the electronic element 10 include, for example, an imaging element such as a charge coupled device (CCD) or a complementary metal oxide semiconductor (CMOS), a light emitting element such as a light emitting diode (LED), an element having a sensor function such as pressure, air pressure, acceleration, a gyroscope, or the like, and an integrated circuit.

Note that the electronic element 10 may be disposed on the upper surface of the electronic element mounting substrate 1 with an adhesive interposed therebetween. Examples of the adhesive include a silver epoxy and a thermosetting resin. The electronic element 10 and the electronic element mounting substrate 1 may be electrically connected by, for example, the electronic element bonding members 13.

The electronic device 21 may include a lid 12 bonded to the upper surface of the electronic element mounting substrate 1 and covering the electronic element 10.

For example, when the electronic element 10 is an imaging element such as a CMOS or a CCD, or a light emitting element such as an LED, a member made of a material having high transparency such as a glass material can be used for the lid 12. Further, when the electronic element 10 is an integrated circuit or the like, a metal material, a ceramic material, or an organic material can be used for the lid 12.

The lid 12 may be bonded to the electronic element mounting substrate 1 with a lid bonding member 14 interposed therebetween. Examples of materials for the lid bonding member 14 include a thermosetting resin, a low melting point glass, and a brazing material made of a metal component.

The electronic device 21 includes the electronic element mounting substrate 1 of the present disclosure and thus has excellent reliability. Therefore, the characteristics of the electronic element 10 can be exhibited over a long period of time. Because wiring density in the electronic element mounting substrate 1 can be increased by providing the first clearance portion 7, the second clearance portion 8, and the second metal layer 9, the electronic device 21 can be given high functionality and be downsized.

### Configuration of Electronic Module

An example of the electronic module 31 is illustrated in FIG. 2. The electronic module 31 includes a casing 32 that covers the electronic element 10 included in the electronic device 21. The inclusion of the casing 32 makes it possible to further improve airtightness or reduce the direct application of stress from the outside to the electronic device 21. The casing 32 is made of, for example, a resin or a metal material. FIG. 2 illustrates an example in which the electronic element 10 is covered by the lid bonding member 14 and the lid 12 and is further covered by the casing 32. Note that in the example illustrated in FIG. 2, the casing 32 also covers the side surfaces of the electronic element mounting substrate 1, but may cover the electronic element 10 on the upper surface of the electronic element mounting substrate 1.

A part of the casing 32 may include a lens. Here, one lens or a plurality of lenses may be incorporated, and examples of the material of the lens include resin, glass, and crystal. In addition, the casing 32 may be equipped with a drive device or the like configured to drive up, down, left, and right, and may be electrically connected to a pad or the like located on the surface of the electronic element mounting substrate 1 via a bonding member such as solder. The electronic module 31 with such a configuration is referred to as an imaging module.

Note that the casing 32 may include an opening portion through which an external circuit board can be inserted. If inserting an external circuit board through the opening portion included in the casing 32, after the external circuit board is electrically connected to the electronic element mounting substrate 1, the gap of the opening portion may be sealed with a sealing material such as a resin, such that the inside of the casing 32 is hermetically sealed.

### Method for Manufacturing Electronic Element Mounting Substrate and Electronic Device

Next, an example of a method for manufacturing the electronic element mounting substrate 1 and the electronic device 21 according to the present embodiment will be described. The example of the method for manufacturing indicated below is a method for manufacturing in an example of a multi-piece production example.

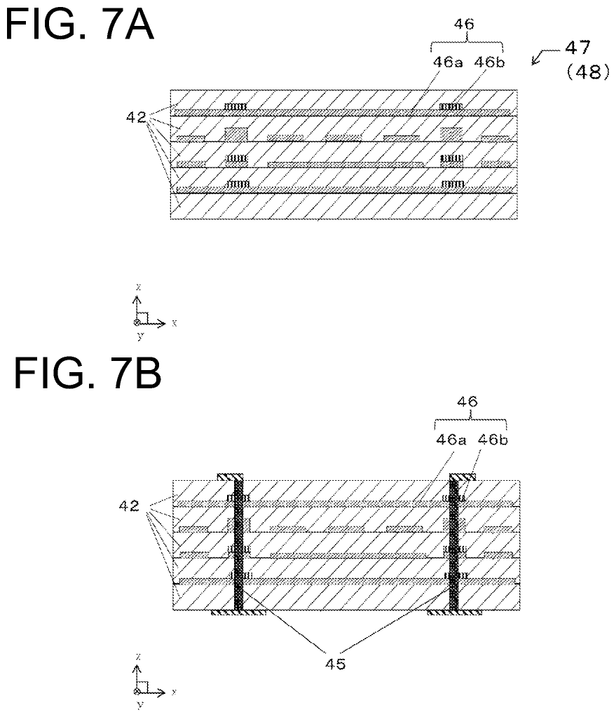

Each of the following steps will be described in detail with reference to FIGS. 6 and 7.

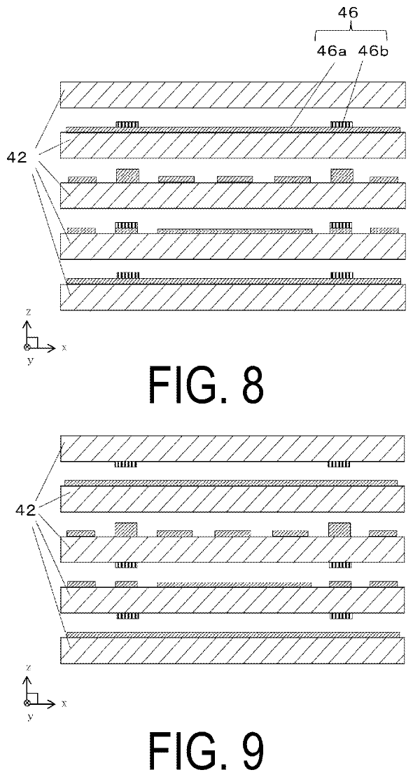

The method for manufacturing the electronic element mounting substrate 1 includes: a first step of preparing a first insulating layer and a second insulating layer; a second step of disposing a first metal layer having different thicknesses on the second insulating layer; a third step of layering the first insulating layer over the second insulating layer with the first metal layer interposed therebetween to obtain a first laminate 47; a fourth step of forming a through hole that extends through the first laminate 47 in a layering direction, the through hole extending through a thick portion of the first metal layer; and a fifth step of forming a through-hole conductor in the through hole. Note that, as illustrated in FIGS. 8 and 9, which will be described later, step A to step E as a method for manufacturing an electronic element mounting substrate in a case where metal paste in a first layer differs from metal paste in a second layer are basically the same as the first step to the fifth step described above. While the first step to the fifth step and step A to step E are described in detail below as steps before firing, the first metal layer, the first insulating layer and the second insulating layer may be prepared, sintered and then disposed, and bonded thereafter to complete production.

Note that the following describes an example in which the first metal layer, the first insulating layer and the second insulating layer are produced by sintering, and thus, in the examples illustrated in FIGS. 6 and 7, paste to be the first metal layer is collectively referred to as a first paste 46, of which a portion to be the first portion is referred to as a first part 46a and a portion to be the second portion is referred to as a second part 46b. Furthermore, green sheets to be the insulating layers are collectively referred to as green sheets 42, a green sheet to be the first insulating layer is referred to as a first green sheet 42a, and a green sheet to be the second insulating layer is referred to as a second green sheet 42b. A metal layer A and a metal layer B may be a metal paste, or may be a pad-like metal layer or a metal layer after being sintered.

First step: First, the green sheets 42 including the first green sheet 42a and the second green sheet 42b are prepared. When the insulating layers are an aluminum oxide (Al₂O₃) sintered compact, a sintering aid powder of, for example, silica (SiO₂), magnesia (MgO), and calcia (CaO) is added to Al₂O₃ powder. Then, a suitable binder, solvent, and plasticizer are added and mixed to form a slurry. Then, a sheet-like formed body is obtained by a formation method, such as the doctor blade method or the calender roll method.

Next, the outer shape of the aforementioned sheet-like formed body is machined by using a mold or the like to obtain the green sheets 42 (FIG. 6A). In this process, a notch, a through hole, or slits for multi-piece production may be formed as the outer shape.

Note that in another example in which the insulating layers are made of a resin, sheet-like insulating layers can be obtained by a transfer molding method, an injection molding method, pressing with a metal mold, or the like. In yet another example in which the insulating layers are made of a glass epoxy resin, sheet-like insulating layers can be obtained by impregnating a base material made of glass fibers with a resin and heat-curing the material at a predetermined temperature.

Second step: Subsequently, the first paste 46 is applied to the second green sheet 42b of the green sheets 42 by screen printing or the like, so that the first part 46a and the second part 46b having a thickness larger than that of the first part 46a are disposed at predetermined positions (FIG. 6B). Here, the second part 46b can be obtained by applying the first paste 46 to a predetermined thickness (thickness of the first part 46a) by a first screen, and then applying the first paste 46 at a predetermined position in a first application region by using a second screen. The first paste 46 is produced to have an appropriate viscosity by adding a suitable solvent and binder to the metal powder formed of the above-described metal material(s) and mixing together. Note that the first paste 46 may also contain glass or ceramic in order to increase the bonding strength with other green sheets 42 to be layered.

In the other green sheets 42, metal paste to be the second metal layer, the electrode pads, and the external circuit connection electrodes may be applied. When the green sheets 42 each have a through hole, the through holes may be filled with the metal paste.

In another example in which the insulating layers are made of a resin, the first metal layer having different thicknesses can be formed by a sputtering method, a vapor deposition method, or the like. Furthermore, the first metal layer may be formed by using a plating method after a metal film is provided on the surface.

Third step: The first green sheet 42a is layered on the second green sheet 42b, to which the first paste 46 including the first part 46a and the second part 46b having a thickness larger than that of the first part 46a is applied, to obtain the first laminate 47 (FIG. 7A). Note that while a two-layer laminate is described herein, it suffices that the first laminate 47 be formed of five green sheets 42 layered on one another according to the example illustrated in FIG. 6. Note that a portion to be a cutout section or a recessed section may be formed with a metal mold or the like after the first laminate 47 is obtained.

Fourth step: Subsequently, a mold is used to form through holes that extend through the thick portions of the first metal layer in the layering direction (first direction), that is, extend through the first laminate 47 including the second part 46b. Examples of a method of forming each through hole include molding, and also punching or using a laser.

Fifth step: The through holes formed in the fourth step are filled with the above-described metal paste or the like to form the through-hole conductors 45. FIG. 7B illustrates a configuration in which the through-hole conductors 45 are formed in the first laminate 47.

Subsequently, split grooves are formed at predetermined positions in the first laminate 47 provided with the through-hole conductors 45 by using a metal mold, punching, a slicing device, a laser, or the like. Note that the split grooves can be formed by using a slicing device after firing.

Subsequently, the first laminate 47 provided with the through-hole conductors 45 is fired at a temperature ranging from approximately 1500° C. to 1800° C. to obtain a sintered compact. Note that, in this step, the first paste 46 described above is fired at the same time as the green sheets 42 to form the first metal layer. The same applies to the through-hole conductors, the second metal layer, the electrode pads, and the external circuit connection electrodes.

The resulting sintered compact can then be divided into pieces to obtain electronic element mounting substrates. The sintered compact need only be divided by being broken along the split grooves formed in advance. Alternatively, the sintered compact may be divided by using a slicing device, without forming any split grooves. Note that, before or after the dividing, plating may be applied to the electrode pads, the external circuit connection electrodes, and the surface of each metal layer that is exposed at the time of forming the sintered compact, by using an electrolytic or electroless plating method.

An electronic element is then mounted on the resulting electronic element mounting substrate, whereby an electronic device can be obtained. The electronic element is electrically bonded to the electronic element mounting substrate by the electronic element bonding members. At this time, an adhesive or the like may be used to fix the electronic element to the electronic element mounting substrate.

Furthermore, the resulting electronic device can be provided with a casing that covers the electronic element to obtain an electronic module.

As in the example illustrated in FIG. 8, the second part 46b can be formed with different metal pastes for the first layer and the second layer.

As in the example illustrated in FIG. 9, the second part 46b can be obtained by applying metal paste to each of the predetermined positions on the first green sheet 42a to be the first insulating layer and the second green sheet 42b to be the second insulating layer, and then layering the insulating layers on one another. Compared to a case where metal paste is printed multiple times on the same surface, meaning that the printed region of the second layer is on the metal paste of the first layer, the above-described method allows the printed region to be laid on the green sheets 42, whereby there is less risk of adhesion of the metal paste to the screens and lowered printing accuracy due to such adhesion, which facilitates the printing.

### Second Embodiment

The first metal layer 6 may be, for example, a signal line. In general, unlike power supply and ground potential patterns, a signal line is in communication with other wiring lines through a single through-hole conductor 5. For this reason, higher reliability is required for electrical connection between the through-hole conductor 5 and the signal line. In this regard, with a structure in which the signal line (the first metal layer 6) includes the second portion 6b as in the present embodiment, the reliability of electrical connection can be enhanced.

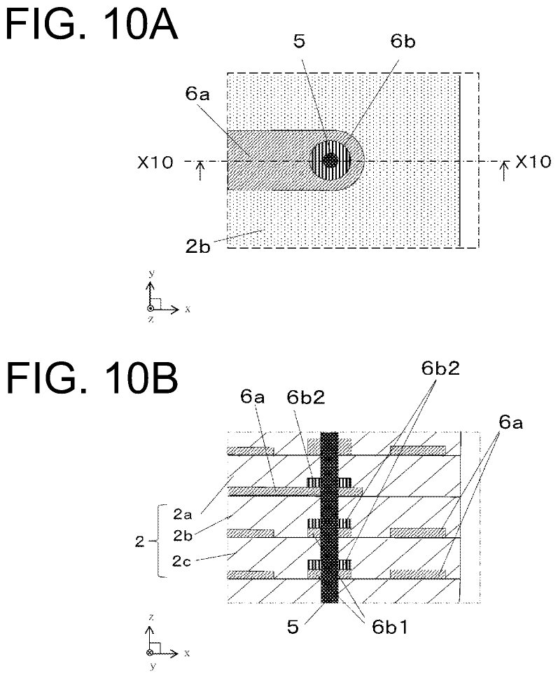

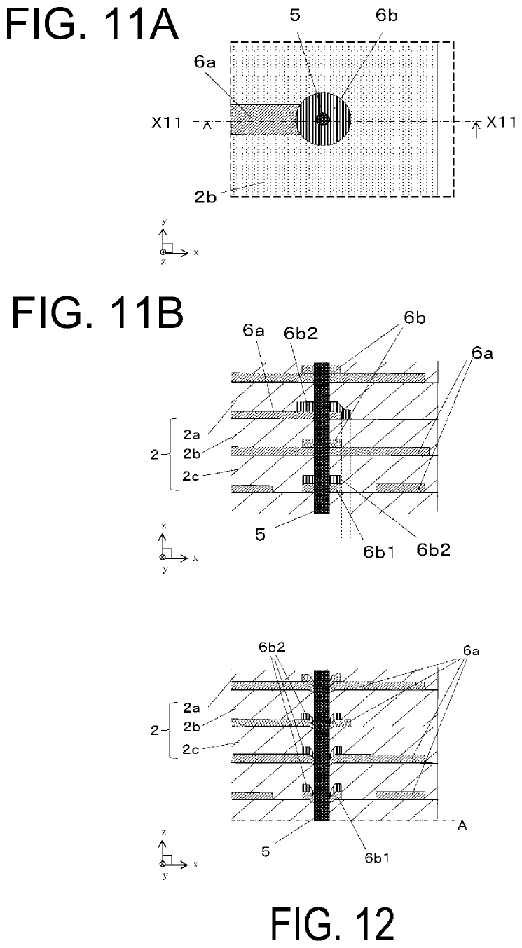

An example of the signal line is illustrated in FIG. 10. FIG. 10 illustrates an example in which, when viewed in a plane perspective in the first direction, the first portion 6a is larger in the x direction and the y direction than the second portion 6b, which is positioned in contact with the through-hole conductor 5, and extends toward the negative side in the x direction.

### Third Embodiment

Another example of the signal line is illustrated in FIG. 11. FIG. 11 illustrates an example in which the first portion 6a is smaller in the y direction than the second portion 6b, which is positioned in contact with the through-hole conductor 5, and extends from the second portion 6b toward the negative side in the x direction with respect to the second portion 6b.

Furthermore, as in the example illustrated in FIG. 11B, the second layer 6b2 may be positioned so as to be in contact with the insulating layer 2 on the lower side. When such a configuration is satisfied, the second portion 6b has a slope. Compared to a case where the upper portion of the second portion 6b has a steep edge in FIG. 11B, stress on the insulating layer 2 corresponding to this edge is reduced, resulting in excellent reliability of mechanical characteristics.

### Fourth Embodiment

As illustrated in FIG. 12, the first insulating layer 2a may include a region sandwiched between the first metal layer 6 and the through-hole conductor 5 in a direction orthogonal to the first direction. When such a configuration is satisfied, the through-hole conductor 5 and the first metal layer 6 can be suppressed from expanding when heat is generated in or transferred to the through-hole conductor 5 and the first metal layer 6.

### Fifth Embodiment

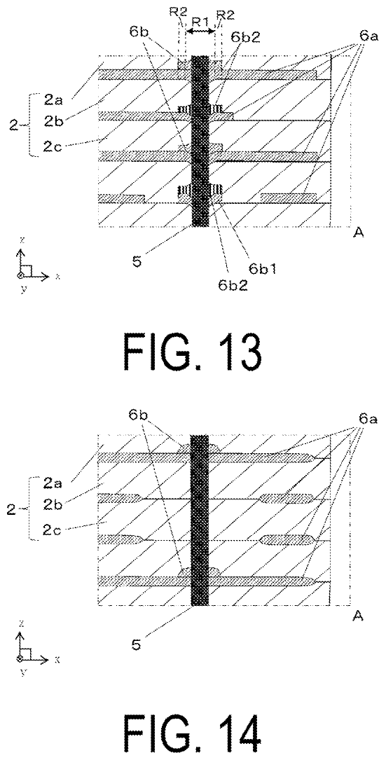

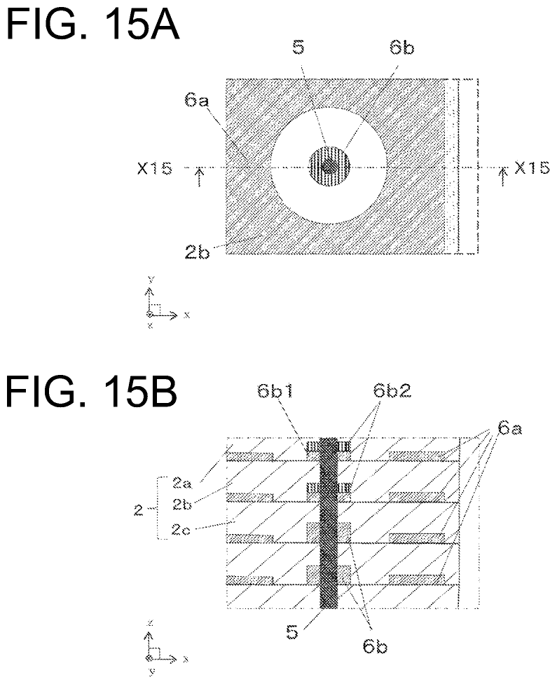

Next, another example of the second portion 6b will be described with reference to FIG. 13.

As illustrated in FIG. 13, the thickness of the second portion 6b may increase closer toward the through-hole conductor 5. When such a configuration is satisfied, the connection reliability between the through-hole conductor 5 and the first metal layer 6 including the second portion 6b is excellent. Furthermore, when such a configuration is satisfied, an upward sloping portion that slopes toward the through-hole conductor 5 is provided. Compared to a case where the insulating layer 2 has steep corners in contact with the through-hole conductor 5 and the second portion 6b, the stress on the corners of the insulating layer 2 is reduced, and excellent reliability of mechanical characteristics is achieved.

As a method for manufacturing the electronic element mounting substrate 1 illustrated in FIG. 13, for example, after the metal paste to be the first portion 6a and the second portion 6b is applied and a laminate of the green sheets is produced, in a step of providing a through hole in a portion to be the through-hole conductor 5, the pin of a mold is caused to follow the second layer 6b2 by reducing the speed at which the pin is released after being pressed, whereby the shape illustrated in FIG. 13 can be achieved.

### Sixth Embodiment

Now, another example of the second portion 6b will be described with reference to FIG. 14.

As illustrated in FIG. 13, the second portion 6b includes a first region R1 in contact with the through-hole conductor 5, and a second region R2 aligned with the first region R1 in a direction orthogonal to the first direction and positioned farther from the through-hole conductor 5 than the first region R1. The second region R2 may have a smaller thickness than that of the first region R1. In other words, the second portion 6b may have a smaller thickness at portions away from the through-hole conductor 5 in the direction orthogonal to the first direction. When such a configuration is satisfied, voids are less likely to be generated in portions farther from the through-hole conductor 5 in the direction orthogonal to the first direction than the second portion 6b. The same applies to the first portion 6a.

An example of a cross-sectional shape where a portion away from the through-hole conductor 5 has a small thickness in the direction orthogonal to the first direction is a lens shape. Here, “lens shape” means that the thickness of the second portion 6b reduces along a curved surface in the cross-sectional view closer toward portions away from the through-hole conductor 5 in the direction orthogonal to the first direction.

As described above, when the second portion 6b has a lens shape, the risk of voids being generated can be further reduced.

The present disclosure is not limited to the above-described embodiments, and various modifications can be made to numerical values and the like. Further, for example, in the examples illustrated in the respective figures, the electrode pads 3 have a rectangular shape in a top view, but may be circular or have another polygonal shape. The arrangement, number, and shape of the electrode pads 3, the mounting method of the electronic element, and the like in the above-described embodiments are not specified. Note that various combinations of characteristic portions of the above-described embodiments are not limited to the examples in the above-described embodiments. Further, the combinations of the respective embodiments are also possible.

### REFERENCE SIGNS LIST

1 Electronic element mounting substrate
2 Insulating layer
2a First insulating layer
2b Second insulating layer
2c Third insulating layer
3 Electrode pad
4 Mounting region
5 Through-hole conductor
6 First metal layer
6a First portion
6b Second portion
6b1 First layer
6b2 Second layer
6c Other metal layer
7 First clearance portion
8 Second clearance portion
9 Second metal layer
10 Electronic element
12 Lid
13 Electronic element bonding member
14 Lid bonding member
21 Electronic device
31 Electronic module
32 Casing
42 Green sheet
42a First green sheet
42b Second green sheet
45 Through-hole conductor
46 Metal layer (metal paste)
46a First portion
46b Second portion
47 First laminate
48 Second laminate
R1 First region
R2 Second region

1. An electronic element mounting substrate comprising:
a first insulating layer and a second insulating layer aligned in a first direction;
a first metal layer positioned between the first insulating layer and the second insulating layer; and
a through-hole conductor extending in the first direction from the first insulating layer through the second insulating layer, wherein
the first metal layer comprises a first portion positioned away from the through-hole conductor and a second portion in contact with the through-hole conductor, and
the second portion has a larger thickness than the first portion.

2. The electronic element mounting substrate according to claim 1, wherein the second portion is positioned away from the first portion by a first clearance portion.

3. The electronic element mounting substrate according to claim 1, further comprising:
a third insulating layer aligned with the second insulating layer in the first direction; and
a second metal layer positioned between the second insulating layer and the third insulating layer, wherein
the through-hole conductor extends in the first direction from the first insulating layer through the third insulating layer, and
the through-hole conductor is positioned away from the second metal layer by a second clearance portion.

4. The electronic element mounting substrate according to claim 3, wherein the second clearance portion is positioned in the second portion in a plan perspective in the first direction.

5. The electronic element mounting substrate according to claim 3, wherein the second portion is positioned in the second clearance portion in a plan perspective in the first direction.

6. The electronic element mounting substrate according to claim 1, wherein
the second portion comprises a first region in contact with the through-hole conductor, and a second region aligned with the first region in a direction orthogonal to the first direction and positioned farther from the through-hole conductor than the first region, and
the second region has a smaller thickness than the first region.

7. The electronic element mounting substrate according to claim 1, wherein the first insulating layer comprises a region sandwiched between the first metal layer and the through-hole conductor in a direction orthogonal to the first direction.

8. An electronic device comprising:
the electronic element mounting substrate described in claim 1; and
an electronic element mounted on the electronic element mounting substrate.

9. An electronic module comprising:
the electronic device described in claim 8; and
a casing that covers the electronic element included in the electronic device.

10. A method for manufacturing an electronic element mounting substrate, the method comprising:
a first step of preparing a first insulating layer and a second insulating layer;
a second step of disposing a first metal layer having different thicknesses on the second insulating layer;
a third step of layering the first insulating layer over the second insulating layer with the first metal layer interposed therebetween to obtain a first laminate;
a fourth step of forming a through hole that extends through the first laminate, the through hole extending through a thick portion of the first metal layer in a layering direction; and
a fifth step of forming a through-hole conductor in the through hole.

11. A method for manufacturing an electronic element mounting substrate, the method comprising:
a step A of preparing a metal layer A, a metal layer B, a first insulating layer, and a second insulating layer;
a step B of disposing the metal layer A and the metal layer B at least partially overlapping each other between the first insulating layer and the second insulating layer;
a step C of sequentially layering the first insulating layer, the metal layer A, the metal layer B, and the second insulating layer to obtain a second laminate;
a step D of forming a through hole that extends through the second laminate, the through hole extending through a portion at which the metal layer A and the metal layer B overlap each other in a layering direction; and
a step E of forming a through-hole conductor in the through hole.
